(19) United States
(12) Patent Application Publication
(10) Pub. No.: US 2006/0091562 A1
(43) Pub. Date: May 4, 2006

(54) Flip chip BGA process and package with stiffener ring

(76) Inventor: Hsin-Hui Lee, Kaohsiung (TW)

Correspondence Address: DUANE MORRIS, LLP;IP DEPARTMENT, 30 SOUTH 17TH STREET, PHILADELPHIA, PA, 19103-4196, US

(21) Appl. No.: 10/978,008

(22) Filed: Oct. 29, 2004

(51) Int. Cl. H01L 23/48

(52) U.S. Cl. 257/778

(57) ABSTRACT

An assembly comprises a substrate, a ring structure bonded to a first side of the substrate; and a die flip-chip-bonded to a second side of the substrate opposite the first side.

### FIELD OF THE INVENTION

The present invention relates to semiconductor packages generally, and more specifically to flip chip ball grid array packages.

### BACKGROUND

The flip chip ball grid array (FCBGA) structure and methods for its fabrication are well known. FIGS. 1A to 1E show a first conventional process for fabricating an FCBBA package.

FIG. 1A shows a package substrate 102, which is baked prior to package assembly. In the example, the substrate 102 is an organic substrate, such as a glass/epoxy substrate. The substrate may have a plurality of levels, with electrical paths between layers provided by interconnect vias (not shown).

FIG. 1B shows the substrate 102 of FIG. 1A, to which a semiconductor integrated circuit (IC) die 104 is flip chip bonded. The die 104 has an array of bonding pads on an active surface thereof, to which respective solder balls 106 are connected. The die 104 is flipped so that its active surface faces the substrate 102. The substrate 102 has a plurality of contacts located at positions which correspond to the locations of the solder balls 106 on the die 104, when the die is in the flipped position. Heat is applied to reflow the solder balls 106, to make the electrical and mechanical connections between the die 104 and the substrate 102.

FIG. 1C shows the step of flushing the space between the active surface of the die 104 and the substrate 102. A solvent 108 such as water may be used to clean out any flux or residue. Any suitable solvent 108 may be used.

FIG. 1D shows the introduction of an underfill material 110 in the space between the die 104 and the substrate 102. The underfill 110 protects the electrical interconnections 106 from mechanical stresses during thermal cycling. The underfill material 110 may be an epoxy or other known underfill material.

FIG. 1E shows a plurality of solder balls 112 formed on terminal pads of the substrate 102, to complete the structure 100. The solder balls 112 can be heated to reflow the solder and form the electrical and mechanical connection between the IC package 100 and the PC board 150.

FIGS. 2A-2F show another conventional packaging method. FIGS. 2A to 2C represent the same fabrication steps described above regarding FIGS. 1A to 1C, respectively. The corresponding structures including package substrate 202, die 204, solder balls 206, and solvent 208 can be the same as described above with reference to items 102, 104, 106 and 108, respectively, and a description of each is not repeated for brevity.

In FIG. 2D, after applying the underfill 210, a one-piece heatspreader 211 is joined to the package. The one-piece heat spreader 211 has a plate section and sidewalls connected to the plate section. The plate section is bonded to the non-active surface of the die 204, and the bottom of the sidewalls contacts the substrate 202. The plate section may be connected to the non-active surface of the die using a thermal interface material, such as an adhesive, a conductive adhesive such as a silver filled epoxy, thermal grease, solder or a phase change material. Similarly, the sidewalls may be connected to the substrate 202 using a thermal interface material.

FIG. 2E shows a plurality of solder balls 212 formed on terminal pads of the substrate 202, to complete the package 200.

FIG. 2F shows a printed circuit board 214, to which the package 200 is attached. The solder balls 212 are reflowed by heat, to make mechanical and electrical connections between the package 200 and the printed circuit board 214. A heat sink 216 may be connected to the heat spreader 211.

One problem shown in FIG. 2F is the possibility of shorting between the reflowed solder balls 212 when the package 200 is joined to the printed circuit board 214. This is likely to occur if a heavy weight is placed on the package 200, and the solder balls collapse. This may occur, for example, during application of surface mount technology (SMT).

Moreover, another problem arises as package sizes increase, according to the recent trend towards high performance devices with large package size. During the baking step (FIGS. 1A and 2A), the substrate 102, 202 tends to warp. If the warpage is substantial, then one or more of the solder interconnections between the die 104, 204 and the substrate 102, 202, respectively, may miss-bond, or may have an inferior quality and fail. Conventional high performance FCBGA processes cannot provide good warpage control of the substrate 102, 202 for a large package (e.g., 40×40 mm or larger) with a one-piece heat spreader 211. For example, in a 27×27 mm package, warpage is less than 6 mils (0.15 mm). In a 37.5×37.5 mm package, warpage less than 10 mils (0.25 mm) becomes difficult to maintain, and half or more of the substrates may not meet this criterion.

FIGS. 3A-3E show a conventional method of handling the substrate warpage problem using a two-piece heatspreader 303, 311. The corresponding structures including package substrate 302, die 304, solder balls 306, solvent 308 and underfill 310 can be the same as described above with reference to items 102, 104, 106, 108, and 110, respectively, and a description of each is not repeated for brevity.

In FIG. 3A, a stiffener ring 303 is bonded to the substrate 302 using a thermally conductive interface material, prior to baking the substrate. The stiffener ring 303 substantially reduces or eliminates warpage of the substrate 302 during baking. Then the die 304 is mounted to the substrate 302 by solder balls 306 (FIG. 3B); the space between the die 304 and the substrate 302 is flushed with solvent 308 (FIG. 3C); and the plate section 311 of the heat spreader is connected to the non-active surface of the die 304 and to the stiffener ring 303 to form a complete heat spreader (FIG. 3D). The solder balls 312 are then attached to the substrate 302.

Although the method of FIGS. 3A-3E eliminates or reduces the warpage of the substrate 302, it introduces another problem. The ring 303 blocks the flow of solvent 308, so that the flux cleaning step of FIG. 3C has a poor cleaning efficiency. As a result, flux residue can remain after the cleaning step. The flux residue can cause corrosion and voids in the underfill 310. Voids in the underfill can result in unfavorable thermal stress distributions during thermal cycling of the package, leading to solder connection failure.

Further, the method of FIGS. 3A-3E does not address the problem of short circuits between solder balls 212, as shown in FIG. 2F. The solder balls 212 can still collapse and short together.

An improved method and structure is desired.

### SUMMARY OF THE INVENTION

An assembly comprises: a substrate, a ring structure bonded to a first side of the substrate, and a die flip-chip-bonded to a second side of the substrate opposite the first side.

A method for packaging comprises the steps of: bonding a ring structure to a first side of a substrate, and flip-chip-bonding a die to a second side of the substrate opposite the first side.

### BRIEF DESCRIPTION OF THE DRAWINGS

FIGS. 1A-1E are diagrams showing a conventional process for fabricating an FCBGA package without a heat spreader.

FIGS. 2A-2F are diagrams showing a conventional process for fabricating a printed circuit board having an FCBGA package with a one-piece heat spreader mounted thereon.

FIGS. 3A-3E are diagrams showing a conventional process for fabricating an FCBGA package with a two-piece heat spreader.

FIGS. 4A-4H are diagrams showing an exemplary process for fabricating a printed circuit board having a high performance FCBGA package mounted thereon.

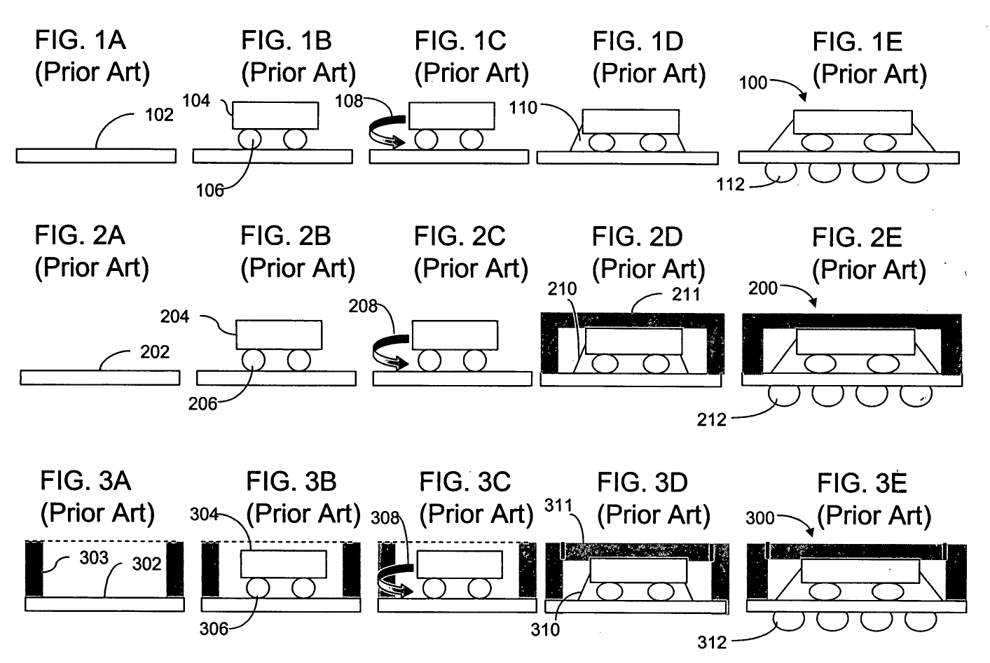

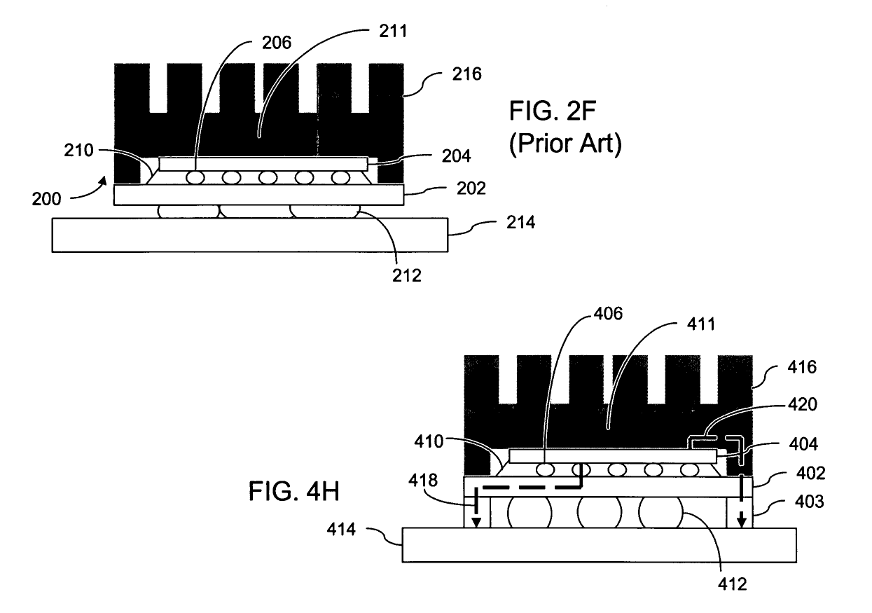

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,”etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

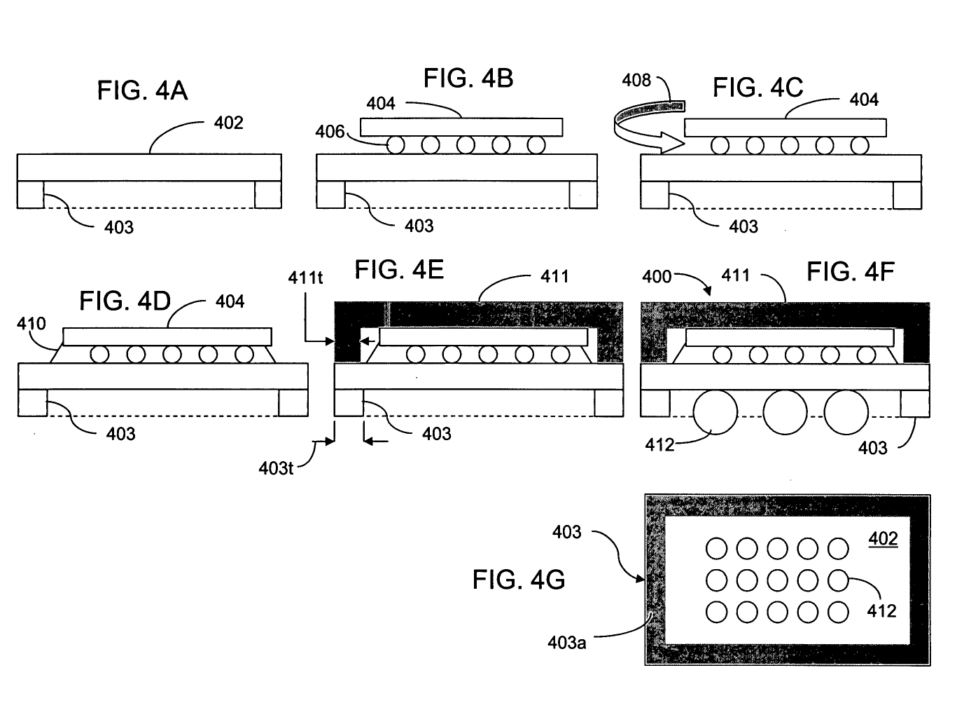

FIG. 4A shows a package substrate 402. In FIG. 4A, a stiffener ring 403 is bonded to a first side of the substrate 402 using a thermally conductive interface material, prior to baking the substrate. The ring is attached using a material, such as solder, an adhesive, or a conductive adhesive such as a silver filled epoxy, thermal gel, or silver paste. The substrate 402 and stiffener ring 403 are baked prior to package assembly. The stiffener ring 403 substantially reduces or eliminates warpage of the substrate 402 during baking. In the example, the substrate 102 is an organic substrate, such as a glass/epoxy substrate. The substrate may have a plurality of levels, with electrical paths between layers provided by interconnect vias (not shown).

It is understood by one of ordinary skill in the art that the term “ring” as used herein is not limited to a round structure. For example, the ring 403 can be rectangular for a rectangular substrate 402, or may have an irregular shape corresponding to the perimeter of an irregularly shaped substrate (not shown).

FIG. 4B shows the substrate 402 of FIG. 4A, to which a semiconductor integrated circuit (IC) die 404 is flip chip bonded. The die 404 has an array of bonding pads on an active surface thereof, to which respective solder balls 406 are connected. The die 404 is flipped so that its active surface faces the substrate 402. The substrate has a plurality of contacts located at positions which correspond to the locations of the solder balls 406 on the die 404, when the die is in the flipped position. Heat is applied to reflow the solder balls 406, to make the electrical and mechanical connections between the die 404 and the substrate 402.

FIG. 4C shows the step of flushing the space between the active surface of the die 404 and the substrate 402. A solvent 408 such as water may be used to clean out any flux or residue. Any suitable solvent 408 may be used. Because the ring 403 is on the first side of the substrate 402, and the die 404 is on the second (opposite) side of the substrate, the ring 403 does not interfere with the ingress or egress of the fluid 408 into the space between the substrate 402 and the die 404. The flux can be thoroughly removed, avoiding the likelihood of corrosion or voids in the underfill 410.

FIG. 4D shows the introduction of the underfill material 410 in the space between the die 404 and the substrate 402. Because the ring 403 is on the first side of the substrate 402, and the die 404 is on the second (opposite) side of the substrate, the ring 403 does not interfere with the application of the underfill material 410 into the space between the substrate 402 and the die 404. This improved access to the space to be filled between the die 404 and substrate 404 may further reduce the likelihood of voids in the underfill. The underfill material 410 may be an epoxy or other known underfill material suitable for protecting the electrical interconnections 406 from mechanical stresses during thermal cycling.

In FIG. 4E, after applying the underfill 410, a heat spreader 411, which may be a one-piece heatspreader, is joined to the package. The one-piece heat spreader 411 has a plate section and sidewalls connected to the plate section. The plate section is interfaced to the non-active surface of the die 404, and the bottom of the sidewalls contacts the substrate 402. Either the plate or the sidewalls or both is attached by an adhesive, a conductive adhesive such as a silver filled epoxy, or by solder. One, but not both, of the plate and sidewall interfaces may optionally be made using a thermal interface material, such as thermal grease, or a phase change material. That is, at least one of the plate and the sidewalls is positively attached by adhesive, such as die attachment material or epoxy, or solder. As apparent from FIG. 4E, the sides 403a of the ring structure 403 have a thickness 403t greater than or equal to a thickness 411t of side walls of the heat spreader 411. Also, the side walls of the heat spreader contact a perimeter of the substrate, so that the ring structure 403 has sides aligned with the side walls of the heat spreader 411.

In the example, the ring 403 and the heatspreader 411 are both formed of copper. Copper is advantageous because it has high thermal conductivity. Alternative materials include AlSiC and Steel. Other materials having a high thermal conductivity and coefficient of thermal expansion compatible with that of the die 404 may also be used. Although a material with a substantially different coefficient of thermal expansion (such as aluminum) could be used for the heatspreader 411, an elastic thermal interface material would have to be used to accommodate the expansion of the heatspreader, and still conduct heat well. Although the same material can be used for the ring 403 and heat spreader 411, other embodiments are contemplated in which the ring 403 and heat spreader 411 are made of different materials.

FIG. 4F shows a plurality of solder balls 412 formed on terminal pads of the substrate 402, to complete the package 400.

FIG. 4G is a bottom plan view of the package 400 shown in FIG. 4F. FIG. 4G shows how the ring structure 403 has a perimeter approximately matching a perimeter of the substrate. Also, the ring structure 403 has a thickness 403t that is substantially less than a length dimension or a width dimension of the substrate 402. Thus, the ring 403 does not detrimentally reduce the area available for the solder balls 412.

FIG. 4H shows a printed circuit board 414, to which the package 400 is attached. The solder balls 412 are reflowed by heat, to make mechanical and electrical connections between the package 400 and the printed circuit board 414. A heat sink 416 may be connected to the heat spreader 411.

The ring 403 provides an extra thermal conduction path 418 between the die 404 and the printed circuit board 414, by way of the solder balls 406, substrate 402, and ring 403. As shown in FIG. 4H, the side walls of the heat spreader 411 are aligned with walls 403a of the ring structure 403. Thus, an additional conduction path 420 is provided through the heat spreader 411, the periphery of the substrate 402 and the ring 403.

The ring 403 serves a further function of supporting the substrate 402 to prevent shorting between ones of the solder balls 412. Even if a weight is applied to the heat sink 416 or top of the package, the ring 403 acts as a spacer to prevent collapsing or crushing of the solder balls 412. The solder balls 412 are not forced to spread excessively, and the likelihood of a short circuit between solder balls 412 is greatly reduced.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. An assembly comprising:
a substrate;
a ring structure bonded to a first side of the substrate; and
a die flip-chip-bonded to a second side of the substrate opposite the first side.

2. The assembly of claim 1, further comprising a heat spreader having a plate bonded to an inactive surface of the die, the heat spreader having side walls connected to the plate, the side walls contacting a perimeter of the substrate,
wherein the ring structure has sides aligned with the side walls of the heat spreader.

3. The assembly of claim 2, wherein the sides of the ring structure have a thickness greater than or equal to a thickness of side walls of the heat spreader.

4. The assembly of claim 1, further comprising:
an underfill between the die and the substrate;
a heat spreader bonded to an inactive surface of the die; and
a plurality of solder balls on the first side of the substrate, electrically coupled to the die by way of circuitry on the substrate.

5. The assembly of claim 4, further comprising:
a printed circuit board having contacts to which the plurality of solder balls on the first side of the substrate are joined by reflow.

6. The assembly of claim 1, wherein the ring structure is made of copper.

7. The assembly of claim 1, wherein the ring structure has a perimeter approximately matching a perimeter of the substrate.

8. The assembly of claim 7, wherein the ring structure has a thickness substantially less than a length dimension or a width dimension of the substrate.

9. A package comprising:
a package substrate having electrical contacts on a first side thereof;
a ring structure bonded to the first side of the package substrate;
a die flip-chip-bonded to a second side of the package substrate opposite the first side;
a heat spreader having a plate bonded to an inactive surface of the die, the heat spreader having side walls connected to the plate, the side walls contacting a perimeter of the package substrate.

10. The assembly of claim 9, wherein the ring structure has sides aligned with the side walls of the heat spreader.

11. The assembly of claim 10, wherein the sides of the ring structure have a thickness greater than or equal to a thickness of side walls of the heat spreader.

12. The assembly of claim 9, further comprising:
an underfill between the die and the package substrate; and
a plurality of solder balls on the contacts of the first side of the package substrate.

13. The assembly of claim 9, wherein the ring structure is made of copper.

14. The assembly of claim 9, wherein the ring structure has a perimeter approximately matching a perimeter of the package substrate.

15. The assembly of claim 14, wherein the ring structure has a thickness substantially less than a length dimension or a width dimension of the package substrate.

16. A method for packaging, comprising the steps of:
(a) bonding a ring structure to a first side of a substrate; and
(b) flip-chip-bonding a die to a second side of the substrate opposite the first side.

17. The method of claim 16, further comprising cleaning a space between an active face of the die and the substrate after step (b).

18. The method of claim 16, further comprising baking the substrate between step (a) and step (b).

19. The method of claim 18, further comprising cleaning a space between an active face of the die and the substrate after step (b).

20. The method of claim 19, further comprising:
applying an underfill between the die and the substrate after the cleaning step;
bonding a heat spreader to an inactive surface of the die; and
mounting a plurality of solder balls on the first side of the substrate.

21. the method of claim 20, further comprising reflowing the solder balls to join the substrate to a printed circuit board having contacts to which the plurality of solder balls are joined.

22. The method of claim 21, further comprising supporting the substrate with the ring structure to prevent shorting between ones of the solder balls.

23. The method of claim 16, further comprising:
aligning side walls of a heat spreader with walls of the ring structure, the heat spreader having a plate section connected to the side walls;
bonding the side walls to a perimeter of the substrate, and
bonding the plate section of the heat spreader to an inactive surface of the die.
